(19) United States
(12) Patent Application Publication
(10) Pub. No.: US 2015/0200313 A1
(43) Pub. Date: Jul. 16, 2015

(54) DISCONTINUOUS EMITTER AND BASE ISLANDS FOR BACK CONTACT SOLAR CELLS

(71) Applicant: Solexel, Inc., Milpitas, CA (US)

(72) Inventors: Mehrdad M. Moslehi, Los Altos, CA (US); Pawan Kapur, Burlingame, CA (US); Karl-Josef Kramer, San Jose, CA (US)

(21) Appl. No.: 14/596,213

(22) Filed: Jan. 13, 2015

Related U.S. Application Data
(60) Provisional application No. 61/926,852, filed on Jan. 13, 2014.

(51) Int. Cl. H01L 31/0224; H01L 31/0725

(52) U.S. Cl. CPC H01L 31/022441; H01L 31/0725

(57) ABSTRACT

Back contact solar cells having a discontinuous emitter comprising a plurality of emitter islands are provided. The back contact solar cell comprises a semiconductor layer with a background base doping and having a sunlight-receiving frontside and a backside opposite said sunlight-receiving frontside. An emitter layer having a doping opposite said semiconductor layer background doping is positioned on the semiconductor layer backside. A trench isolation pattern partitions the emitter layer and semiconductor layer into a plurality of discontinuous emitter regions on the semiconductor layer backside. At least one base island region contacting the semiconductor layer is positioned within each of the discontinuous emitter regions on the semiconductor layer backside.

### CROSS-REFERENCE TO RELATED APPLICATIONS

This application claims the benefit of U.S. provisional patent application 61/926,852 filed on Jan. 13, 2014, which is hereby incorporated by reference in its entirety.

### FIELD OF THE INVENTION

The present disclosure relates in general to the fields of solar photovoltaic (PV) cells, and more particularly to back contact solar cells.

### BACKGROUND

As photovoltaic solar cell technology is adopted as an energy generation solution on an increasingly widespread scale, fabrication and efficiency improvements relating to solar cell efficiency, metallization, material consumption, and fabrication are required. Generally, solar cell contact structure includes emitter and base diffusion regions contacting conductive metallization—for example metallization connecting silicon in base and emitter contact areas through relatively heavy phosphorous and boron areas, respectively.

Manufacturing cost and conversion efficiency factors are driving solar cell absorbers ever thinner in thickness and larger in area, thus, increasing the mechanical fragility, efficiency, and complicating processing and handling of these thin absorber based solar cells—fragility effects increased particularly with respect to crystalline silicon absorbers.

### BRIEF SUMMARY OF THE INVENTION

Therefore, a need has arisen for improved back contact solar cell structures and fabrication processes that provide increased solar cell performance. In accordance with the disclosed subject matter, back contact solar cells having a discontinuous emitter comprising a plurality of emitter islands are provided which may substantially eliminate or reduces disadvantage and deficiencies associated with previously developed for back contact solar cells.

According to one aspect of the disclosed subject matter, back contact solar cells having a discontinuous emitter comprising a plurality of emitter islands are provided. The back contact solar cell comprises a semiconductor layer with a background base doping and having a sunlight-receiving frontside and a backside opposite said sunlight-receiving frontside. An emitter layer having a doping opposite said semiconductor layer background doping is positioned on the semiconductor layer backside. A trench isolation pattern partitions the emitter layer and semiconductor layer into a plurality of discontinuous emitter regions on the semiconductor layer backside. At least one base island region contacting the semiconductor layer is positioned within each of the discontinuous emitter regions on the semiconductor layer backside.

In another embodiment, a back contact solar cell comprises a semiconductor layer with a background base doping and having a sunlight-receiving frontside and a backside opposite said sunlight-receiving frontside. An emitter layer having a doping opposite said semiconductor layer background doping is positioned on the semiconductor layer backside. A doped base boundary pattern partitions the emitter layer and semiconductor layer into a plurality of discontinuous emitter regions on the semiconductor layer backside. At least one base island region contacting the semiconductor layer is positioned within each of the discontinuous emitter regions on the semiconductor layer backside.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1A is a representative schematic plan view diagram of a discontinuous emitter solar cell having square-shaped emitter islands isolated by trench isolation border;

FIG. 1B is a representative schematic plan view diagram of a discontinuous emitter solar cell having square-shaped emitter islands defined by doped base partitioning borders;

FIGS. 2A and 2B are schematic cross-sectional diagrams of a monolithic semiconductor substrate on a backplane showing formation of emitter island trench isolation or partitioning regions;

FIGS. 3A and 3B are schematic cross-sectional diagrams of a monolithic semiconductor substrate showing formation of emitter island doped base partitioning border;

FIGS. 4 and 5 are high level cross-sectional device diagrams showing an expanded and selective simplified view of a single emitter island of a discontinuous emitter solar cell;

FIGS. 6A through 8B shown each cell with an array of 4×4 square-shaped emitter islands forming emitter islands I₁₁ through I₄₄;

FIGS. 9A through 12B shown each cell with 4 triangular-shaped emitter islands forming emitter islands I₁ through I₄; and

FIG. 13 is a schematic showing a solar cell having a plurality of discontinuous triangular emitter islands.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

And although the present disclosure is described with reference to specific embodiments and components, such as a back contact back junction (BCBJ) silicon solar cell, one skilled in the art could apply the principles discussed herein to other solar cell structures solar cell semiconductor materials (such as GaAs, compound III-V materials), fabrication processes (such as various deposition, contact opening, and diffusion methods and materials), as well as absorber/passivation/metallization materials and formation, technical areas, and/or embodiments without undue experimentation.

Discontinuous emitter back contact solar cells may be integrated into existing solar cell fabrication process flows—particularly interdigitated back contact (IBC) back junction solar cell fabrication process flows. Particularly, the discontinuous emitter solar cells provided may utilize, in whole or in part, the fabrication processes and structures found in patent applications U.S. Pub. No. 20140326295 published Nov. 6, 2014, U.S. Pub. No. 2014/0370650 published Dec. 18, 2014, U.S. Pub. No. 20140318611 published Oct. 30, 2014, and U.S. Pub. No. 20130228221 published Sep. 5, 2013, all of which are hereby incorporated by reference in their entirety.

The solar cell having a discontinuous emitter comprising a plurality of emitter islands may be made monolithically (i.e., from a common starting substrate or substrate and cell processing layers such as an emitter layer) on a single starting semiconductor substrate comprising discontinuous emitter. Each back-contact solar cell may be fabricated monolithically using a single starting semiconductor substrate, for example a 156 mm×156 mm or larger pseudo-square or square-shaped crystalline silicon wafers or alternative geometrical wafer shape including but not limited to circular, rectangular, or other polygonal shapes. Interdigitated back contact (IBC) discontinuous emitter photovoltaic (PV) solar cell structure embodiments using crystalline semiconductor absorbers (e.g., silicon) may provide improved and relatively high conversion efficiencies for example in some instances in the range of 20-25% PV cell efficiencies and greater than 18% module efficiencies. Solar cell structure may comprise a backplane-attached semiconductor (e.g., crystalline Si) structure or in some embodiments be formed as a solar cell without an attached backplane.

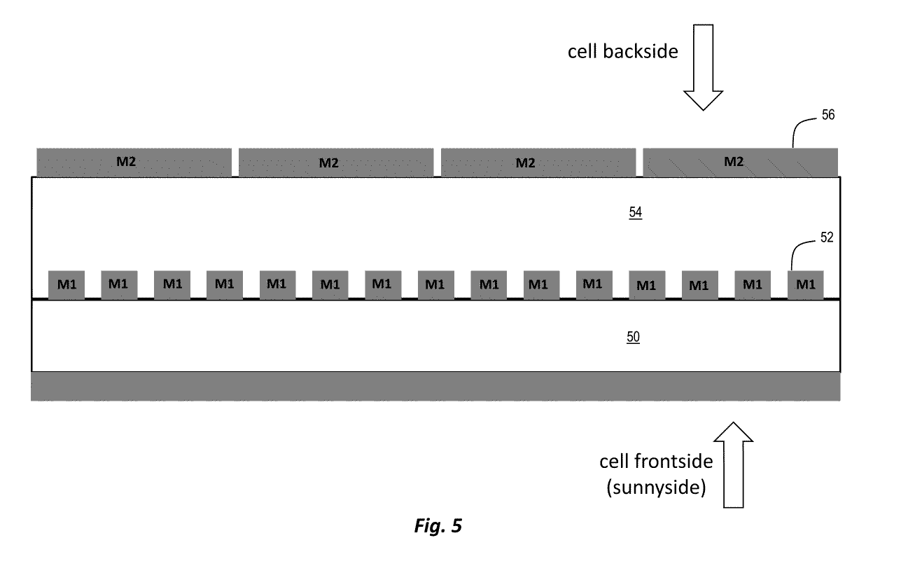

Additional advantages of discontinuous emitter solar cells having a plurality of monolithically partitioned emitter islands include: the ability to scale up the voltage and scale down the current of the monolithically-fabricated solar cell when using trench isolation borders to create trench-partitioned emitter islands; may be readily integrated with high-performance/low-cost power electronics for applications such as integrated shade management and cell-level MPPT power harvesting maximization; may be readily integrated with backplane attached back contact solar cells utilizing two level metallization (e.g., M1 and M2 layers such as that shown in FIG. 5); provide enhanced cell flexibility (isolating trenches may reduce cell cracking) and reduced weight using a combination of thin semiconductor absorber layers and flexible backplanes.

The present application provides back contact solar cells and fabrication methods thereof having discontinuous emitter comprising a plurality of discontinuous emitter regions (emitter “islands”). Each emitter island may be formed using a pn junction (e.g., p+ doped emitter junction in an n-type silicon substrate). Optionally, each emitter island may be formed as selective emitter comprising a less heavily doped (e.g., p+) field emitter and more heavily doped metallization contact regions. Discontinuous emitter regions/islands may be formed as a plurality of (i.e. at least two) emitter islands, with each emitter island partitioned from its surrounding islands using a border/boundary. The island-partitioning boundaries may be formed, in two embodiments, by isolating trenches formed through the entire semiconductor absorber layer attached to a backplane (such as that described in detail in U.S. Pub. No. 20140326295 published Nov. 6, 2014 and U.S. Pub. No. 2014/0370650 published December 18 referenced above and both of which are incorporated by reference herein in their entirety) or by closed-loop doped base borders (e.g., with n-type base doping) surrounding each of the emitter islands (e.g., the emitter junction within each emitter island having a p-type doping). Thus, the solar cell structure comprises a plurality of emitter islands which may be separated from each other as follows: (i) closed loop peripheral base (e.g., n type) rim boundaries surrounding and encompassing emitter (e.g., p+ doped emitter) islands; (ii) backplane-attached monolithic trench isolation boundaries; or, (iii) a combination of (i) and (ii).

The number of emitter islands on the solar cell may be at least two and up to as many as desired (e.g., N×N with N being an integer or up to 10's or even 100's of emitter islands). Additionally, emitter islands within a solar cell substrate may have either uniform or variable areas, and may have any one or a combination of geometrical shapes including: squares, rectangles, triangles, hexagons, polygons, or other geometrical shapes.

Within each emitter island (with the plurality of emitter islands forming the discontinuous emitter region of the solar cell) there is a plurality of base islands (i.e., base diffusion regions) with doping polarity opposite to that of emitter doping polarity (e.g., a plurality of n-type base islands within each p-type emitter island). In other words, each emitter island (e.g., p-type emitter junction formed with boron doping in an n-type semiconductor cell substrate) comprises and encompasses a plurality of base islands (e.g., n-type base region doped with phosphorus in an n-type semiconductor cell substrate). These base islands may be formed using known solar cell base diffusion region formation methods such as patterned dopant deposition and anneal.

The base islands may have either uniform or variable areas and may be formed as a plurality or combination of rectangular interdigitated fingers, circles, squares, rectangles, triangles, hexagons, other polygonal shapes, or other geometrical shapes (e.g., ellipses). Each of the plurality of base islands within each emitter island may have a more heavily doped surface region (for instance, n+ doped region) compared to the lighter background base doping (for instance, n-type background base doping).

Thus, each solar cell comprising a plurality of emitter islands may be considered a plurality of sub-cells with each sub-cell corresponding to an emitter island. Fabrication advantages include, but are not limited to, in-line electrical measurements and extraction of electrical parametrics at the smaller-area sub-cell granularity, and facilitating enhanced in-line process control capabilities to improve the overall manufacturing process uniformities and tightening of cell parametrics distributions, resulting in increased manufacturing yield and reduction of the number of efficiency bins.

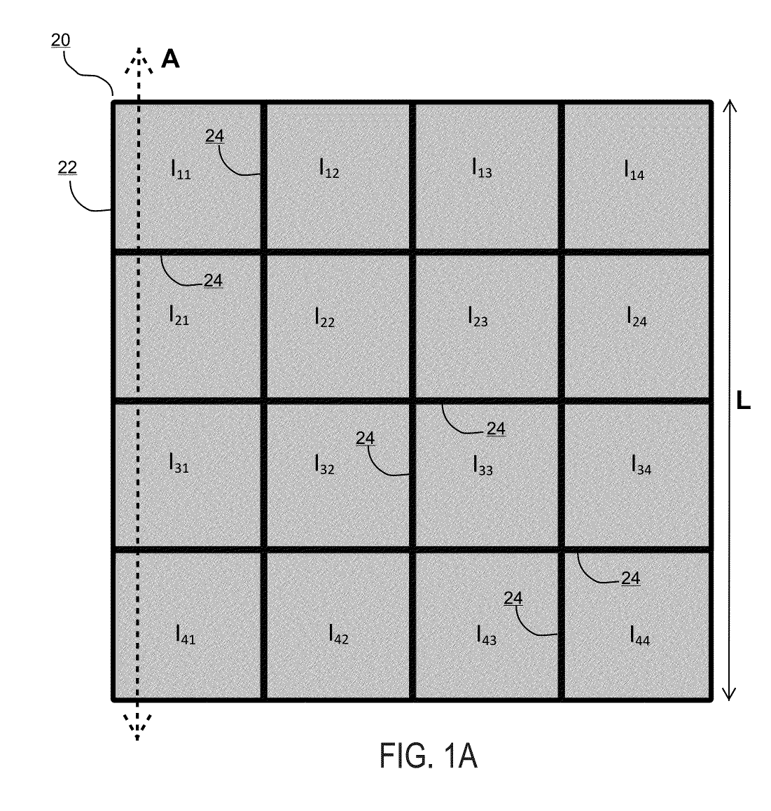

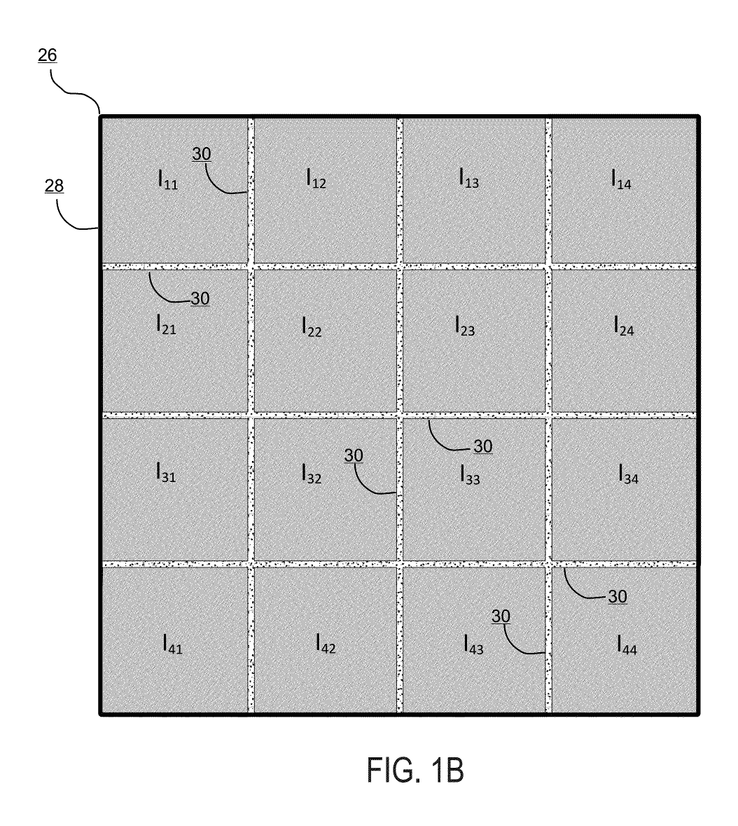

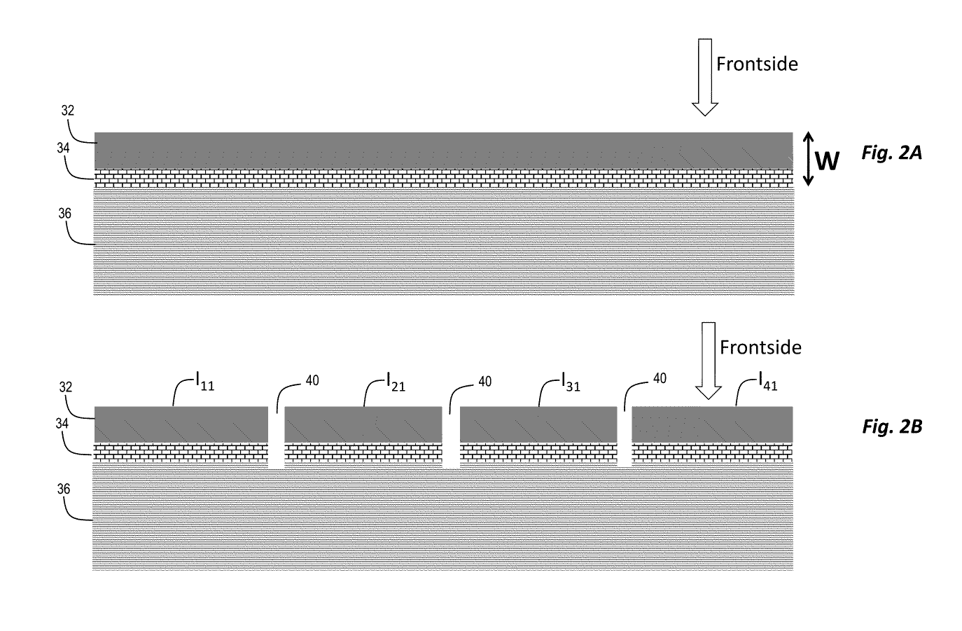

FIG. 1A is a representative schematic plan view diagram of a discontinuous emitter solar cell (shown with square-shaped emitter islands in a square-shaped) having 16 uniform-size (equal-size) square-shaped emitter islands or sub-cells (N×N=4×4=16 emitter islands) isolated by partitioning borders. This schematic diagram shows a plurality of emitter islands (shown as 4×4=16 islands) partitioned by partitioning borders 24. FIG. 1A is a schematic diagram of a top or plan view of a 4×4 uniform solar cell 20 defined by cell peripheral boundary or edge region 22, having a side length L, and comprising sixteen (16) uniform square-shaped emitter regions formed from an original continuous substrate and identified as I₁₁ through I₄₄ attached to a continuous backplane on the cell backside (backplane and solar cell backside not shown). Each emitter island or region is defined by an internal peripheral boundary (for example, an isolation trench cut through the cell semiconductor substrate thickness and having a trench width substantially smaller than the island side dimension, with the trench width no more than 100's of microns and in some instances less than or equal to about 100 μm—for instance, in the range of a few up to about 100 μm) shown as trench isolation or emitter island partitioning borders 24. Cell peripheral boundary or edge region 22 has a total peripheral length of 4 L; however, the total cell edge boundary length comprising the peripheral dimensions of all the emitter islands comprises cell peripheral boundary 22 (also referred to as cell outer periphery) and trench isolation borders 24. Edge-induced losses may be mitigated by proper passivation of the solar cell edge regions and through isolation/separation of the emitter junction region from the edge region (hence, providing allowance for larger edge area fraction without loss of solar cell efficiency).

FIGS. 2A and 2B are schematic cross-sectional diagrams of a monolithic semiconductor substrate on a backplane before formation of emitter island trench isolation or partitioning regions, and a monolithic discontinuous emitter solar cell on a backplane after formation of emitter island trench isolation or partitioning regions, respectively. FIG. 2B shows a simplified cross-sectional view of the backplane-attached solar cell after formation of the emitter partitioning trenches to the backplane to define the discontinuous emitter islands consistent with the cell of FIG. 1A. FIG. 2B shows a schematic cross-sectional view of the cell of FIG. 1A along the view axis A of FIG. 1A and having uniform-size square-shaped emitter islands (N×N=4×4=16 islands).

FIG. 2A comprises semiconductor substrate 32 and emitter layer 34 having width (semiconductor layer thickness) W and attached to backplane 36 (e.g., an electrically insulating continuous backplane layer, for instance, a thin flexible sheet of prepreg). FIG. 2B is a cross-sectional diagram of a discontinuous emitter solar cell—shown as a cross-sectional diagram along the A axis of the cell of FIG. 1A. Shown, FIG. 2B comprises emitter islands I₁₁, I₂₁, I₃₁, and I₄₁ each having a trench-partitioned emitter islands having layer width (thickness) W and attached to backplane 36. The emitter islands are physically and electrically isolated by an internal peripheral partitioning boundary, emitter island trench partitioning borders 40. Emitter islands I₁₁, I₂₁, I₃₁, and I₄₁ are monolithically formed from the same continuous semiconductor substrate shown in FIG. 2A as semiconductor substrate 32 and emitter layer 34. The cell of FIG. 2B may be formed from the semiconductor/backplane structure of FIG. 2A by forming internal peripheral partitioning boundaries in the desired emitter island shapes (e.g., square shaped) by trenching through the semiconductor layer to the attached backplane (with the trench-partitioned emitter regions being supported by the continuous backplane). Trench partitioning of the semiconductor substrate to form the emitter islands does not partition the continuous backplane sheet, hence the resulting emitter islands remain supported by and attached to the continuous backplane layer or sheet. Trench partitioning formation process through the initially continuous semiconductor substrate thickness may be performed by, for example, pulsed laser ablation or dicing, mechanical saw dicing, ultrasonic dicing, plasma dicing, water jet dicing, or another suitable process. The backplane structure may comprise a combination of a backplane support sheet in conjunction with a patterned metallization structure, with the backplane support sheet providing mechanical support to the semiconductor layer and structural integrity for the resulting discontinuous emitter cell (either a flexible solar cell using a flexible backplane sheet or a rigid solar cell using a rigid backplane sheet or a semi-flexible solar cell using a semi-flexible backplane sheet). The term backplane may refer to the combination of the continuous backplane support sheet and patterned metallization structure or to refer to the backplane support sheet (for instance, an electrically insulating thin sheet of prepreg) which is attached to the semiconductor substrate backside and supports both the cell semiconductor substrate regions and the overall patterned solar cell metallization structure.

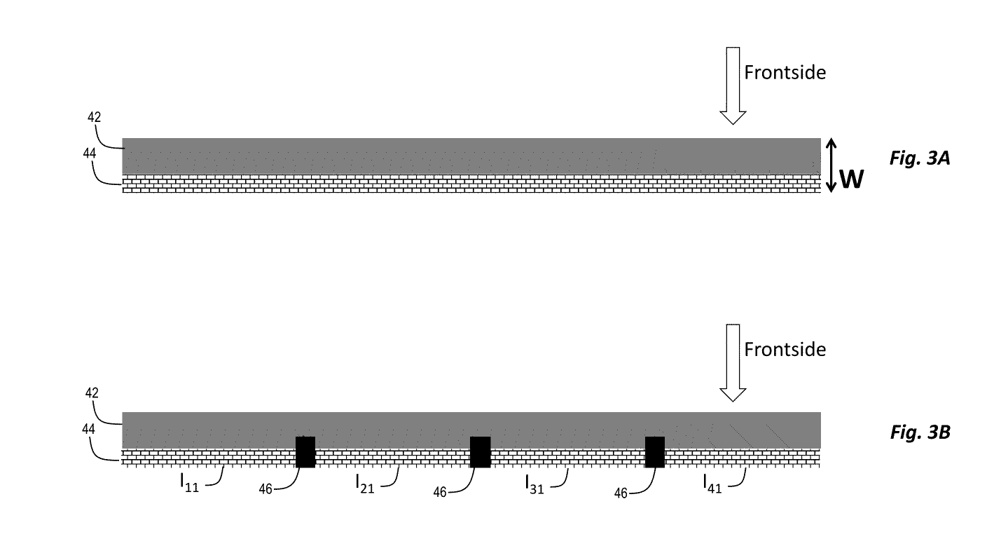

In another embodiment, emitter partitioning borders may be formed using doped base partitioning borders. FIG. 1B is a representative schematic plan view diagram of a discontinuous emitter solar cell (shown with square-shaped emitter islands in a square-shaped) having 16 uniform-size (equal-size) square-shaped emitter islands or sub-cells (N×N=4×4=16 emitter islands) defined by doped base partitioning borders 30. FIG. 1B is a schematic diagram of a backside view of a 4×4 uniform solar cell 28 defined by cell peripheral boundary or edge region 26, having a side length L, and comprising sixteen (16) uniform square-shaped emitter regions formed from an original continuous substrate and identified as I₁₁ through I₄₄ attached to a continuous backplane on the cell backside (backplane and solar cell backside not shown). Each emitter island or region is defined by internal doped base partitioning peripheral boundary 30. FIGS. 3A and 3B are schematic cross-sectional diagrams of a monolithic semiconductor substrate before formation of emitter island doped base partitioning border, and a monolithic discontinuous emitter solar cell on after formation of emitter island doped base partitioning border, respectively. These doped base partitioning boundaries may be formed using known solar cell base diffusion region formation methods such as patterned dopant deposition and anneal.

FIG. 3A comprises semiconductor substrate 42 and emitter layer 44 having width (semiconductor layer thickness) W. FIG. 3B is a cross-sectional diagram of a discontinuous emitter solar cell consistent with the cell of FIG. 1B—and shown as a cross-sectional diagram along the A axis of the cell of FIG. 1B. Shown, FIG. 3B comprises emitter islands I₁₁, I₂₁, I₃₁, and I₄₁ each having doped based partitioned emitter islands having layer width (thickness) W. In other words, an internal doped base closed loop partitioning boundary, doped base partitioning borders 46 define the discontinuous emitter islands. Emitter islands I₁₁, I₂₁, I₃₁, and I₄₁ are monolithically formed from the same continuous semiconductor substrate shown in FIG. 3A as semiconductor substrate 42 and emitter layer 44. The cell of FIG. 3B may be formed from the semiconductor structure of FIG. 3A by forming internal peripheral partitioning boundaries in the desired emitter island shapes (e.g., square shaped) by forming doped base regions in the emitter layer to the semiconductor layer. In some instances, the doped base partitioning of the emitter islands does not partition the semiconductor substrate while partitioning the emitter islands and is thus is shown without a supporting backplane in FIG. 3B. Doped base partitioning borders may be formed through the initially continuous emitter layer by, for example, solar cell base doping diffusion processes.

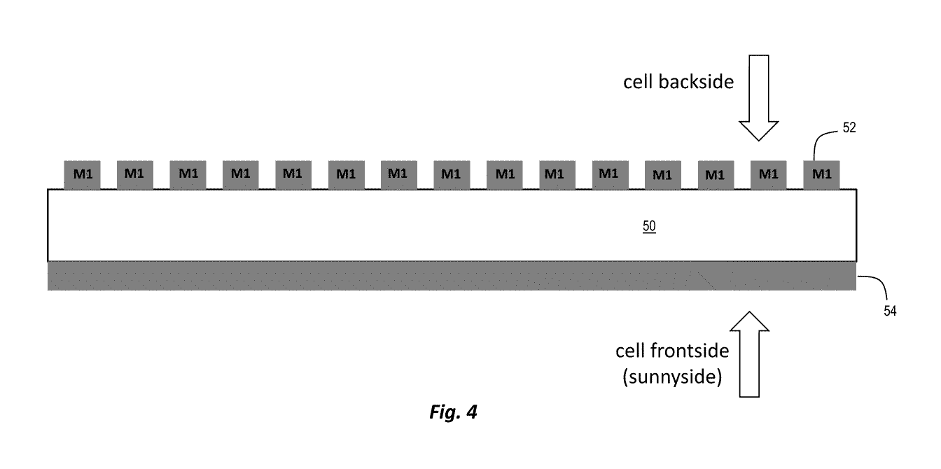

A key advantage of the disclosed discontinuous emitter back contact solar cells is that they may be monolithically fabricated during cell processing and readily integrated into existing solar cell fabrication process flows—particularly interdigitated back contact (IBC) back junction solar cell fabrication process flows. A patterned passivation dielectric layer on the semiconductor backside (i.e., positioned on the emitter layer) may be used reduce surface recombination losses. Contact holes in the patterned passivation dielectric layer may provide access for contacting the emitter layer and base island regions with base and emitter metallization (e.g., M1 or first level metal layer as described herein). FIG. 4 is a high level cross-sectional device diagram showing an expanded and selective simplified view of a single emitter island of a discontinuous emitter solar cell after solar cell fabrication steps consistent with an interdigitated back-contact (IBC) solar cell embodiment. Interdigitated M1 contact metallization 52 contacts base (e.g., base islands) and emitter regions (e.g., emitter layer) on the back side of semiconductor absorber (e.g., silicon) 50, for example through a passivation dielectric layer (not shown). Cell frontside passivation/anti-reflection coating (ARC) layer 54 provides enhanced solar cell advantages. Detailed doped emitter and base regions, optional front-surface field (FSF) and/or optional back-surface field (BSF) regions, contacts for M1 metallization are not shown. FIG. 5 is a high level cross-sectional device diagram showing an expanded and selective simplified view of a single emitter island of a discontinuous emitter solar cell consistent with the cell of FIG. 4 and further including electrically insulating and continuous backplane layer 54 and interdigitated M2 metallization 56 which contacts base and emitter metallization of interdigitated M1 contact metallization 52. Although not shown, interdigitated M2 metallization 56 may patterned orthogonally to M1 layer 52. Conductive via plugs connecting patterned M1 to patterned M2 through electrically-insulating continuous backplane layer 54 not shown. Optionally, each emitter island may be formed as selective emitter comprising a less heavily doped (e.g., p+) field emitter and more heavily doped metallization contact regions.

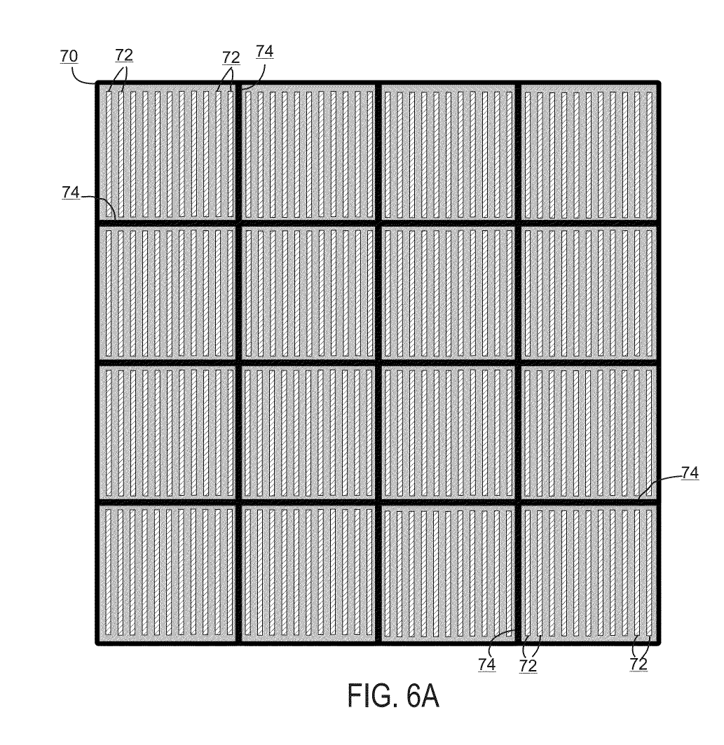

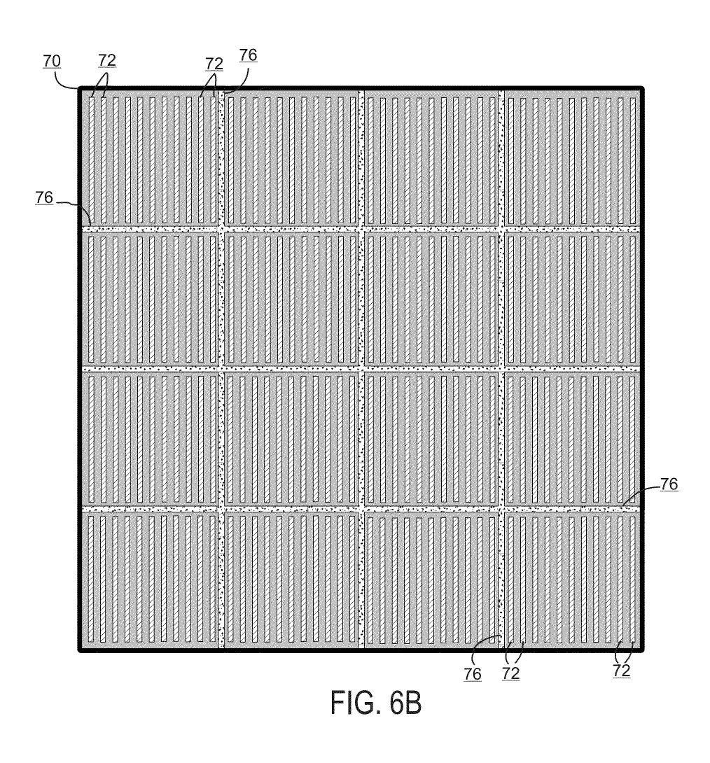

FIGS. 6A through 13 show exemplary embodiments of back contact solar cells having a discontinuous emitter region comprising a plurality of emitter islands. Like aspects of the Figures are similar unless otherwise noted. FIGS. 6A through 8B shown each cell with an array of 4×4 square-shaped emitter islands forming emitter islands I₁₁ through I₄₄ such as that shown in FIGS. 1A and 1B and one of the following partitioning structures: 1) emitter partitioning (or islanding) using trench isolation partitioning borders; or, 2) emitter partitioning (or islanding) using doped base partitioning borders. Each of the plurality of emitter islands includes a plurality of base islands within its boundary.

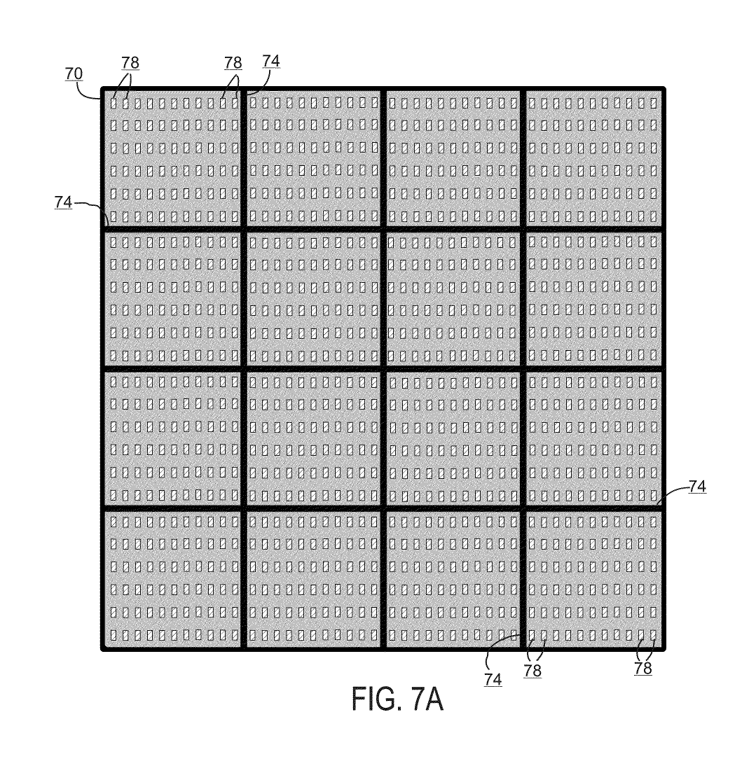

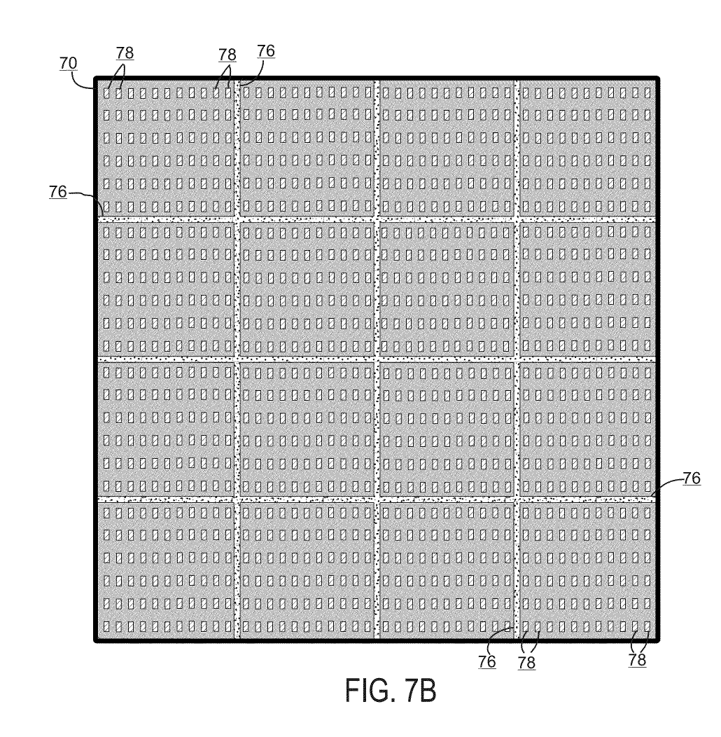

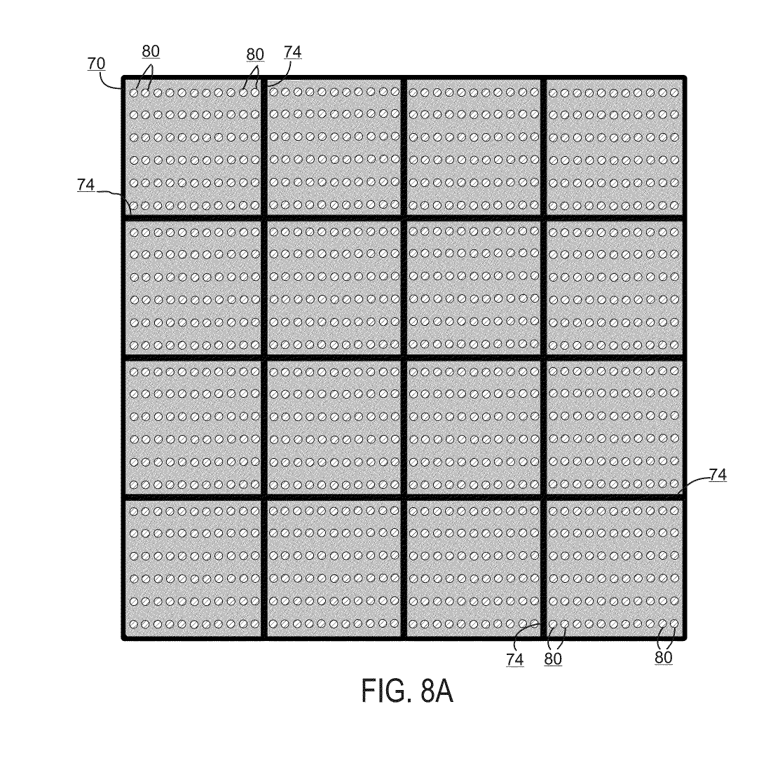

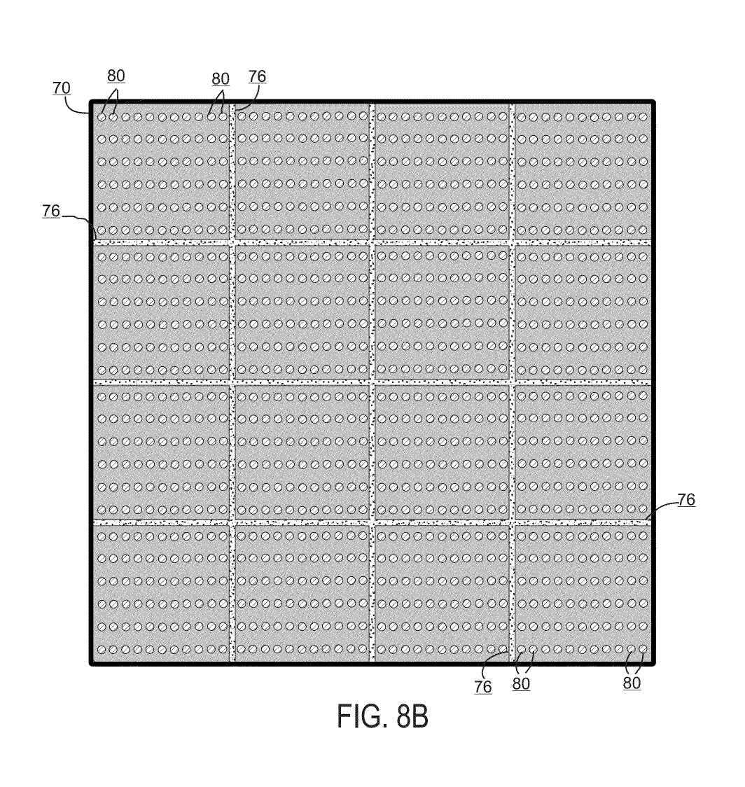

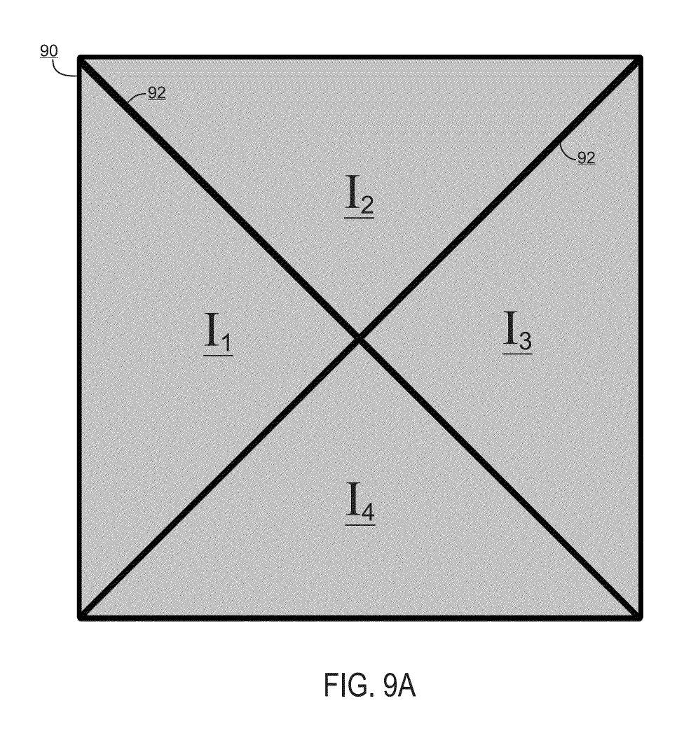

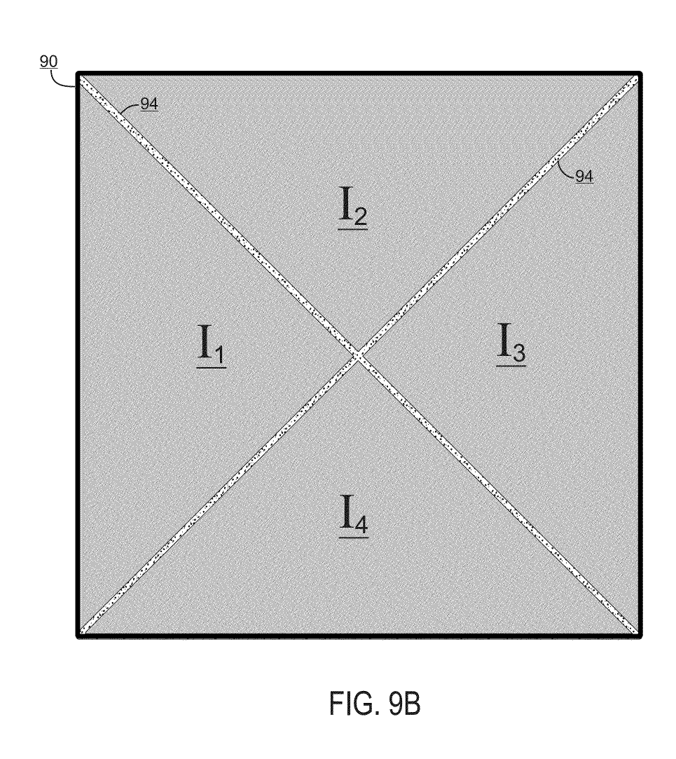

Relating to emitter partitioning (or islanding) using trench isolation partitioning borders (with a backplane sheet, i.e., a backplane-attached solar cell)—each doped (e.g., p+ doped) emitter island further having one of the following base (e.g., n-type base) configurations within its area: plurality of interdigitated rectangular-shaped base fingers (shown in FIG. 6A); a plurality of small-area discrete rectangular base islands (shown in FIG. 7A); and, a plurality of small-area discrete circular base islands (shown in FIG. 8A).

Relating to emitter partitioning (or islanding) using doped base partitioning borders (with or without a backplane sheet, i.e., a backplane-attached cell)—each doped (e.g., p+ doped) emitter island further comprising one of the following base (e.g., n-type base) configurations within its area: a plurality of interdigitated rectangular-shaped base fingers (shown in FIG. 6B); a plurality of small-area discrete rectangular base islands (shown in FIG. 7B); and, a plurality of small-area discrete circular base islands (shown in FIG. 8B).

Numerous other configurations are possible outside of the representative examples provided. For example, the number of square-shaped emitter islands may be N×N wherein N is any number equal to or larger than two (examples shown for 4×4 arrangement). Additionally, the base islands within each emitter island may be made in numerous other geometrical shapes (besides rectangle, square, circle, etc.).

FIG. 6A is a schematic showing a solar cell, defined by peripheral boundary 70, with a plurality of discontinuous emitter islands formed by trench isolation boundaries 74 (such as that shown in FIGS. 1A and 2B) and rectangular interdigitated base islands 72 within each emitter island. FIG. 6B is a schematic showing a solar cell, defined by peripheral boundary 70, with a plurality of discontinuous emitter islands formed by doped base boundaries 76 (such as that shown in FIGS. 1B and 3B) and rectangular interdigitated base islands 72 within each emitter island.

FIG. 7A is a schematic showing a solar cell, defined by peripheral boundary 70, with a plurality of discontinuous emitter islands formed by trench isolation boundaries 74 (such as that shown in FIGS. 1A and 2B) and rectangular (relatively small-area) discrete base islands 78 within each emitter island. FIG. 7B is a schematic showing a solar cell, defined by peripheral boundary 70, with a plurality of discontinuous emitter islands formed by doped base boundaries 76 (such as that shown in FIGS. 1B and 3B) and rectangular (relatively small-area) discrete base islands 78 within each emitter island.

FIG. 8A is a schematic showing a solar cell, defined by peripheral boundary 70, with a plurality of discontinuous emitter islands formed by trench isolation boundaries 74 (such as that shown in FIGS. 1A and 2B) and circular (relatively small-area) discrete base islands 80 within each emitter island. FIG. 8B is a schematic showing a solar cell, defined by peripheral boundary 70, with a plurality of discontinuous emitter islands formed by doped base boundaries 76 (such as that shown in FIGS. 1B and 3B) and circular (relatively small-area) discrete base islands 80 within each emitter island.

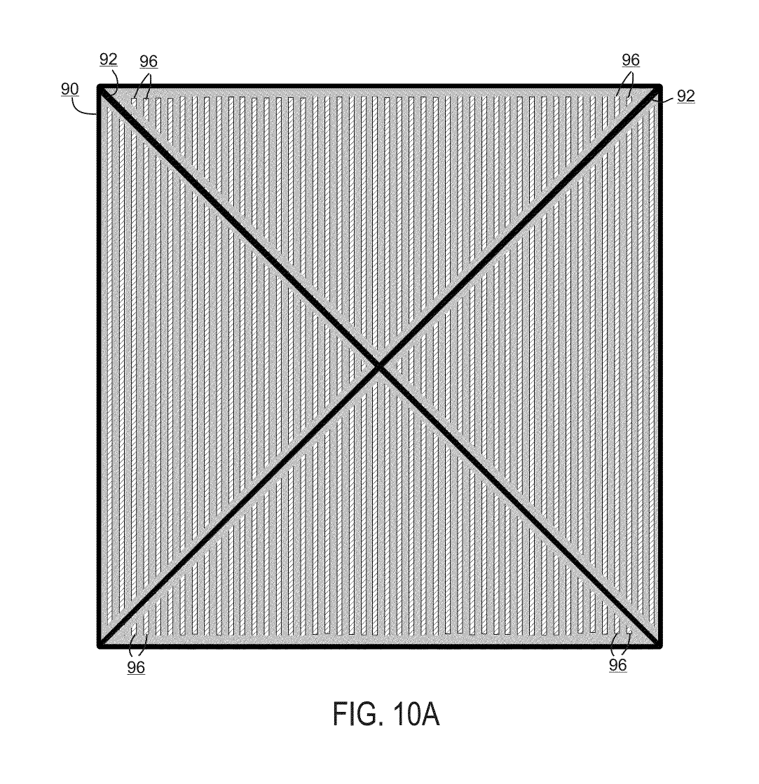

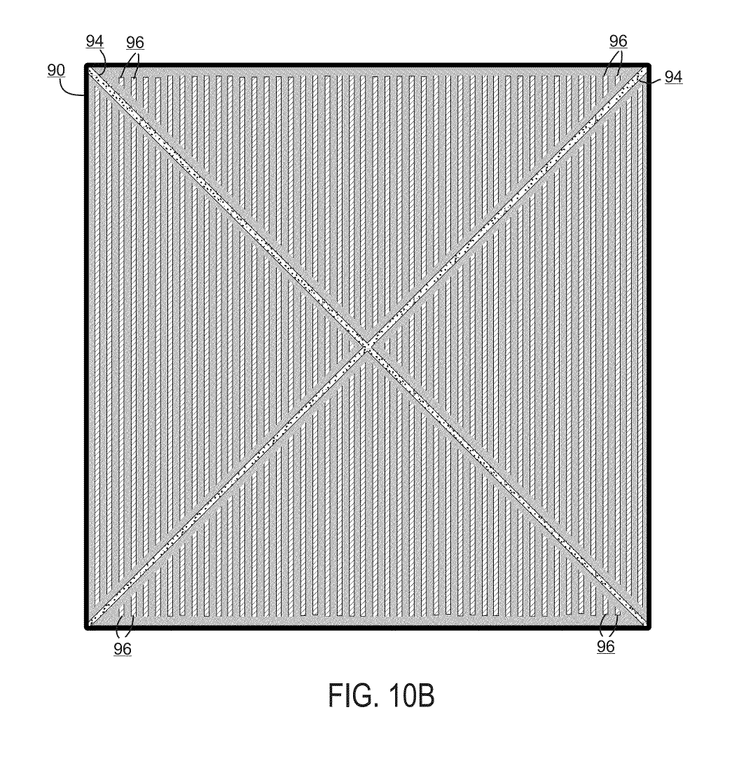

FIGS. 9A through 12B shown each cell with 4 triangular-shaped emitter islands forming emitter islands I₁ through I₄ and one of the following partitioning structures: 1) emitter partitioning (or islanding) using trench isolation partitioning borders; or, 2) emitter partitioning (or islanding) using doped base partitioning borders. Each of the plurality of emitter islands shown in FIGS. 10A through 12B includes a plurality of base islands within its boundary.

FIG. 9A is a schematic showing a solar cell, defined by peripheral boundary 90, with a plurality of discontinuous emitter islands formed by trench isolation boundaries 92 (such as that shown in FIGS. 1A and 2B). FIG. 9B is a schematic showing a solar cell, defined by peripheral boundary 90, with a plurality of discontinuous emitter islands formed by doped base boundaries 94 (such as that shown in FIGS. 1B and 3B).

FIG. 10A is a schematic showing a solar cell, defined by peripheral boundary 90, with a plurality of discontinuous emitter islands formed by trench isolation boundaries 92 (such as that shown in FIGS. 9A and 2B) and rectangular interdigitated base islands 96 within each emitter island. FIG. 10B is a schematic showing a solar cell, defined by peripheral boundary 90, with a plurality of discontinuous emitter islands formed by doped base boundaries 94 (such as that shown in FIGS. 9B and 3B) and rectangular interdigitated base islands 96 within each emitter island.

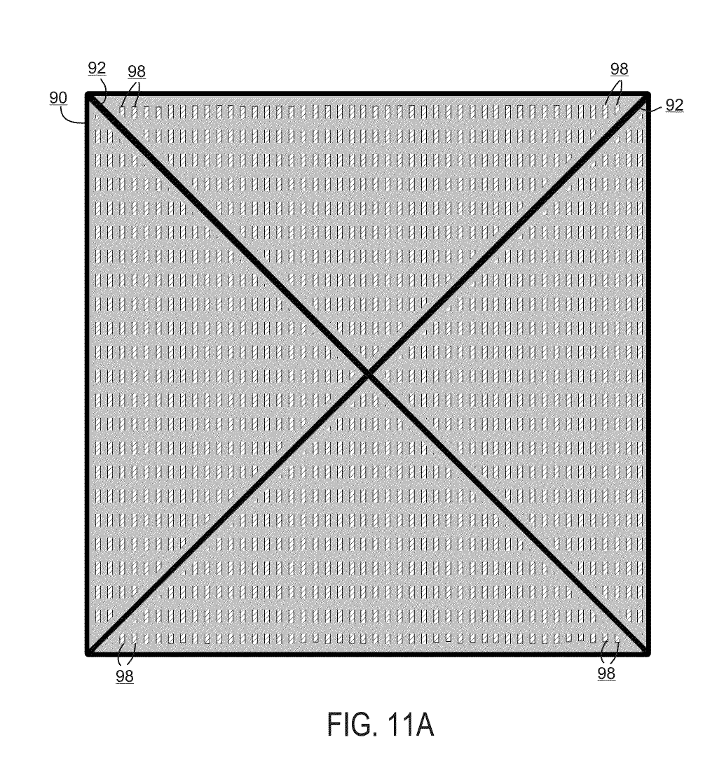

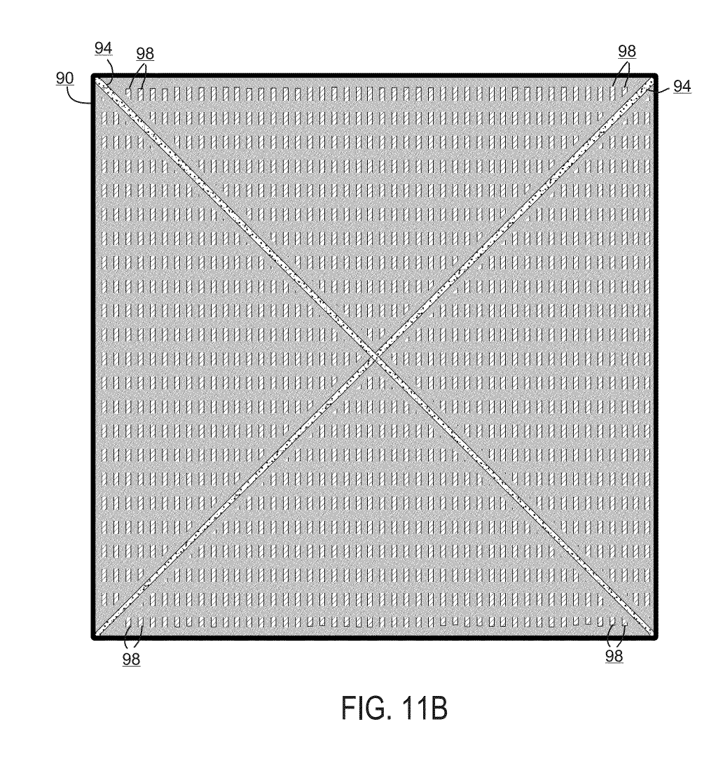

FIG. 11A is a schematic showing a solar cell, defined by peripheral boundary 90, with a plurality of discontinuous emitter islands formed by trench isolation boundaries 92 (such as that shown in FIGS. 9A and 2B) and rectangular (relatively small-area) discrete base islands 98 within each emitter island. FIG. 11B is a schematic showing a solar cell, defined by peripheral boundary 90, with a plurality of discontinuous emitter islands formed by doped base boundaries 94 (such as that shown in FIGS. 9B and 3B) and rectangular (relatively small-area) discrete base islands 98 within each emitter island.

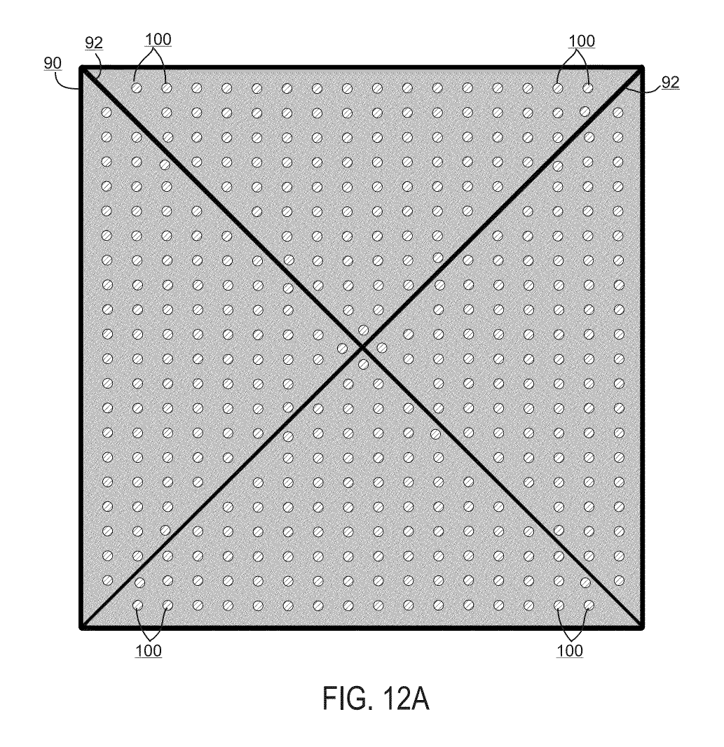

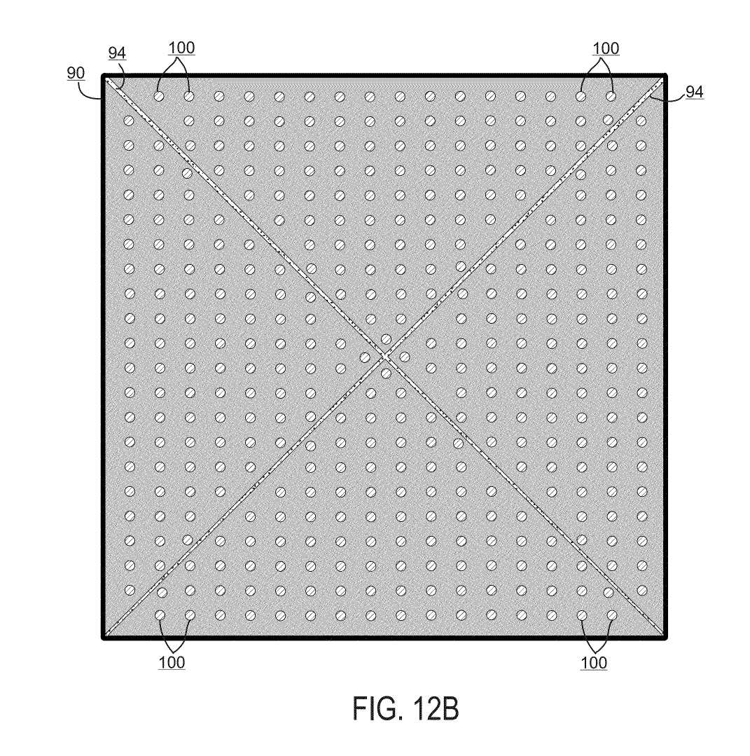

FIG. 12A is a schematic showing a solar cell, defined by peripheral boundary 90, with a plurality of discontinuous emitter islands formed by trench isolation boundaries 92 (such as that shown in FIGS. 9A and 2B) and circular (relatively small-area) discrete base islands 100 within each emitter island. FIG. 12B is a schematic showing a solar cell, defined by peripheral boundary 90, with a plurality of discontinuous emitter islands formed by doped base boundaries 94 (such as that shown in FIGS. 9B and 3B) and circular (relatively small-area) discrete base islands 100 within each emitter island.

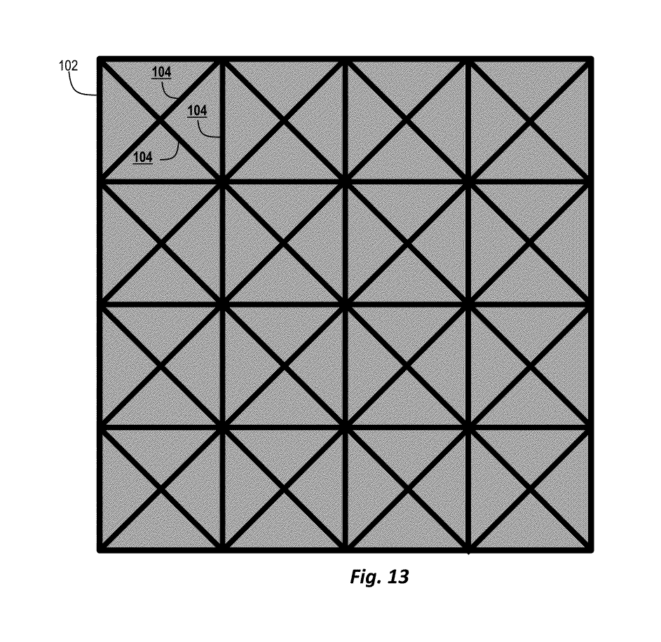

FIG. 13 is a schematic showing a solar cell, defined by peripheral boundary 102, with a plurality of discontinuous triangular emitter islands formed by trench isolation boundaries 104 (such as that shown in FIGS. 1A and 2B) and provided as an example of numerous and various emitter island shapes and sizes.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

1. A back contact back junction solar cell structure comprising:
a semiconductor layer with a background base doping, comprising a sunlight-receiving frontside and a backside opposite said sunlight-receiving frontside;
an emitter layer on said semiconductor layer backside, said emitter layer having a doping opposite said semiconductor layer background doping;
a trench isolation pattern partitioning said emitter layer and semiconductor layer into a plurality of discontinuous emitter regions on said semiconductor layer backside;
at least one base island region within each of said plurality of discontinuous emitter regions on said semiconductor layer backside, said base island region having a base doping contacting said semiconductor layer;
a patterned passivation dielectric layer on said semiconductor backside, said patterned passivation dielectric layer providing contact hole openings to provide access for contacting said base island region and said emitter layer;
a patterned first metal layer (M1) on said patterned passivation dielectric layer on said semiconductor layer backside, said patterned first metal layer having base and emitter contact metallization contacting said base island region and said emitter layer through said contact hole openings;
an electrically insulating continuous backplane support layer attached to said semiconductor layer backside;
a patterned second metal layer (M2) on said electrically insulating continuous backplane support layer, said patterned second metal layer having base and emitter metallization; and
a plurality of electrically conductive via plugs formed through said electrically insulating continuous backplane support sheet interconnecting select portions of said patterned second-level metal layer to select portions of said patterned first-level metal layer.

2. The back contact back junction solar cell of claim 1, wherein said at least one base island region comprises a plurality of base island regions.

3. The back contact back junction solar cell of claim 1, wherein said at least one base island region comprises a plurality of base island regions in a finger island pattern.

4. The back contact back junction solar cell of claim 1, wherein said at least one base island region comprises a plurality of base island regions in a rectangular island pattern.

5. The back contact back junction solar cell of claim 1, wherein said at least one base island region comprises a plurality of base island regions in a squared-shaped island pattern.

6. The back contact back junction solar cell of claim 1, wherein said at least one base island region comprises a plurality of base island regions in a circular island pattern.

7. The back contact back junction solar cell of claim 1, wherein said discontinuous emitter regions are rectangular.

8. The back contact back junction solar cell of claim 1, wherein said discontinuous emitter regions are triangular.

9. The back contact back junction solar cell of claim 1, wherein said discontinuous emitter regions are square-shaped.

10. The back contact back junction solar cell of claim 1, wherein said emitter layer is a field emitter layer and further comprises selective emitter contact metallization regions.

11. A back contact back junction solar cell structure comprising:
a semiconductor layer with a background base doping, comprising a sunlight-receiving frontside and a backside opposite said sunlight-receiving frontside;
an emitter layer on said semiconductor layer backside, said emitter layer having a doping opposite said semiconductor layer background doping;
a doped base boundary pattern partitioning said emitter layer into a plurality of discontinuous emitter regions on said semiconductor layer backside;
at least one base island region within each of said plurality of discontinuous emitter regions on said semiconductor layer backside, said base island region having a base doping contacting said semiconductor layer;
a patterned passivation dielectric layer on said semiconductor backside, said patterned passivation dielectric layer providing contact hole openings to provide access for contacting said base island region and said emitter layer; and
a patterned first metal layer (M1) on said patterned passivation dielectric layer on said semiconductor layer backside, said patterned first metal layer having base and emitter contact metallization contacting said base island region and said emitter layer.

12. The back contact back junction solar cell of claim 11, further comprising:
an electrically insulating continuous backplane support layer attached to said semiconductor layer backside;
a patterned second metal layer (M2) on said electrically insulating continuous backplane support layer, said patterned second metal layer having base and emitter metallization; and
a plurality of electrically conductive via plugs formed through said electrically insulating continuous backplane support sheet interconnecting select portions of said patterned second-level metal layer to select portions of said patterned first-level metal layer.

13. The back contact back junction solar cell of claim 11, wherein said at least one base island region comprises a plurality of base island regions.

14. The back contact back junction solar cell of claim 11, wherein said at least one base island region comprises a plurality of base island regions in a finger island pattern.

15. The back contact back junction solar cell of claim 11, wherein said at least one base island region comprises a plurality of base island regions in a rectangular island pattern.

16. The back contact back junction solar cell of claim 11, wherein said at least one base island region comprises a plurality of base island regions in a squared-shaped island pattern.

17. The back contact back junction solar cell of claim 11, wherein said at least one base island region comprises a plurality of base island regions in a circular island pattern.

18. The back contact back junction solar cell of claim 11, wherein said discontinuous emitter regions are rectangular.

19. The back contact back junction solar cell of claim 11, wherein said discontinuous emitter regions are triangular.

20-21. (canceled)

22. The back contact back junction solar cell of claim 11, wherein said emitter layer is a field emitter layer and further comprises selective emitter contact metallization regions.
